(19) United States
(12) Patent Application Publication
(10) Pub. No.: US 2010/0294341 A1
(43) Pub. Date: Nov. 25, 2010

(54) APPARATUS AND METHODS FOR FRAMELESS BUILDING INTEGRATED PHOTOVOLTAIC PANEL

(76) Inventors: CHRISTOPHER FRANK, Penn Valley, CA (US); John Montello, El Cajon, CA (US); Chris Gopal, La Jolla, CA (US); Mike Curtis, Temecula, CA (US); Anand Janaswamy, Cardiff, CA (US); Mark Farrelly, Carlsbad, CA (US)

Correspondence Address: SHEPPARD, MULLIN, RICHTER & HAMPTON LLP, 12275 EL CAMINO REAL, SUITE 200, SAN DIEGO, CA, 92130, US

(21) Appl. No.: 12/698,850

(22) Filed: Feb. 2, 2010

Related U.S. Application Data
(63) Continuation-in-part of application No. 12/557,436, filed on Sep. 10, 2009.
Application No. 12/557,436 is a continuation-in-part of application No. 12/258,360, filed on Oct. 24, 2008.

(51) Int. Cl. H01L 31/048; H01L 31/0203; B32B 37/12

(52) U.S. Cl. 136/251; 136/259; 156/60

(57) ABSTRACT

The present invention is directed toward apparatus and methods for solar panels capable of rooftop installation. In some embodiments, a low profile solar laminate is provided, comprising: a base layer; a photovoltaic layer; a semi-rigid panel; an ultraviolet resistant layer; wherein a first adhesive adheres the base layer to the semi-rigid panel, a second adhesive adheres the semi-rigid panel to the photovoltaic layer, and a third adhesive adheres the ultraviolet resistant layer to the photovoltaic layer.

### RELATED APPLICATIONS

This application is a continuation-in-part of and claims the benefit of U.S. patent application Ser. No. 12/557,436 filed on Sep. 10, 2009, which is a continuation-in-part of and claims the benefit of U.S. patent application Ser. No. 12/258,360 filed Oct. 24, 2008, the content of which is incorporated herein by reference in its entirety.

### FIELD OF THE INVENTION

The present invention relates to apparatus and methods solar panels, and more particularly, to apparatuses and methods for solar panels capable of rooftop installation.

### DESCRIPTION OF THE RELATED ART

Increasing oil prices and environmental concerns have recently highlighted the desire to decrease the dependence on fossil fuels. This desire has stimulated research into clean and renewable ways to produce electricity for the global marketplace. Solar power is a viable option because it is a clean form of energy with a virtually unlimited supply. Technological innovations and improvements are generally reducing the costs associated with installing, operating, and maintaining solar power equipment. Furthermore, conversion efficiencies have dramatically increased over the years, thereby reducing the size of the equipment necessary to harvest energy produced by the sun.

In some cases, solar energy systems may be used in lieu of oil or other fossil fuels. For example, some solar energy systems may use solar or photovoltaic cells. A solar or photovoltaic (“PV”) cell is a device that converts energy from the sun or other light source into electrical energy. The use of PV cells as an alternative to other sources of energy has generally increased as power costs have increased. For example, some owners of commercial and residential buildings have used certain systems to install PV cells on the top of their buildings to reduce the building's overall dependence on energy provided by utility companies.

Unfortunately, systems for mounting PV cells are generally difficult to install, and are fragile once they are installed. Typically, an installation requires roof racks that may result in roof penetrations and exert wind loads on the roof. Additionally, in order to generate a significant amount of power, the system generally must include a large number of panels with PV cells, which can create issues with wiring and connections to the existing utility systems. Systems for mounting PV cells also tend to lack curb appeal, as they often change the aesthetics of a structure, e.g., a residential structure.

Such disadvantages inspired the creation of building integrated photovoltaic (BIPV) panels, which has distinct advantages over rack mounted PV systems. In comparison to rack mounted PV systems, BIPV panels weigh less, are smaller in size, and lack the need for some system level components that are required by conventional solar energy systems. An example of a building integrated photovoltaic (BIPV) panel is disclosed in parent U.S. patent application Ser. No. 12/258,360, entitled “SOLAR PANELS SYSTEMS AND METHODS,” filed Oct. 24, 2008, the content of which is incorporated herein by reference in its entirety.

At present, BIPV panels that utilize crystalline silicon cells as their photovoltaic cells are constructed in two stages. In the first stage, semi-rigid panels containing the crystalline silicon cells are laminated. In the second stage, the laminated panel is then bonded to a soft and flexible base material or membrane, typically by laying a bead of silicon, epoxy, or urethane calking/adhesive around the perimeter of the laminated panel once the laminated panel is placed on the flexible base material/membrane. The resulting BIPV panel has a drastic transition step between the laminated cells layer (i.e., semi-rigid panel) and the base layer, rendering them susceptible to a number of problems, including de-lamination, moisture integration, and collection of dirt and debris over the life of the BIPV panel.

### BRIEF SUMMARY OF EMBODIMENTS OF THE INVENTION

The present invention is directed toward apparatus and methods for solar panels capable of rooftop installation. In some embodiments, a low profile solar laminate is provided, comprising: a base layer; a photovoltaic layer; a semi-rigid panel; an ultraviolet resistant layer; wherein a first adhesive adheres the base layer to the semi-rigid panel, a second adhesive adheres the semi-rigid panel to the photovoltaic layer, and a third adhesive adheres the ultraviolet resistant layer to the photovoltaic layer. The adhesive material for either first, second, or third adhesives may be a glue, a resin, or a sealant. In addition, any of the adhesives used in the low profile solar laminate may be applied as a either a full or partial layer of adhesive. It should be noted that when the third adhesive is applied as a partial layer of adhesive, the third adhesive should be applied as partial layer such that light passing through the ultraviolet resistant layer can reach the photovoltaic layer. When the third adhesive is applied as a full layer of adhesive, the third adhesive should be of the type that is light-transmissive, thereby allowing light to pass through the third adhesive and reach the photovoltaic layer.

In some embodiments, the base layer is made of polyvinyl chloride (PVC), thermoplastic olefin (TPO), ethylene propylene diene monomer (EPDM), a polyvinyl fluoride (PVF) such as DuPont(™) Tedlar(®), or other electrically insolating material. In further embodiments, the base layer is a roofing material or a roofing membrane. Depending on the embodiment, the base layer may be flexible or rigid.

In other embodiments, the semi-rigid panel is made of a material that can sufficiently support the photovoltaic layer adhered to it. For example, the semi-rigid panel may be constructed of fiber-reinforced plastic (FRP) or advance polymer alloys (APA). Examples of fiber-reinforced plastic include but are not limited to fiberglass-reinforced plastic, aramid fiber-reinforced plastic, and carbon fiber-reinforced plastic.

In additional embodiments, the ultraviolet resistant layer is made of polycarbonate or polyethylene tetrafluoroethylene (ETFE)—such as Tefzel(®) by DuPont(™). In addition, in some embodiments, the photovoltaic cells comprise monocrystalline solar cells or polycrystalline solar cells.

In further embodiments, the low profile solar laminate further comprises a cover sheet adhered to the ultraviolet resistant layer. In some such embodiments, the cover sheet may be disposed onto the ultraviolet resistant layer such that it extends beyond its edge. In other such embodiments, the cover sheet may be disposed on the ultraviolet resistant layer such that it allows for a seam weld to be formed between the low profile solar laminate and a roofing membrane.

Additional embodiments of the invention provide methods for manufacturing a low profile solar laminate in accordance with some of the embodiments described above. In one such embodiment, a method for manufacturing a low profile solar laminate is provided, the method comprising the steps of: applying a first adhesive to a base layer; disposing a semi-rigid panel on the first adhesive; applying a second adhesive to the semi-rigid panel; disposing a photovoltaic layer on the second adhesive; applying a third adhesive to the photovoltaic layer; and disposing an ultraviolet resistant layer on the third adhesive. Additionally, in some such embodiments, the method further comprises the step of disposing a cover sheet onto the ultraviolet resistant layer, wherein an adhesive is used to adhere the cover sheet to the ultraviolet resistant layer.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

Some of the figures included herein illustrate various embodiments of the invention from different viewing angles. Although the accompanying descriptive text may refer to such views as “top,” “bottom” or “side” views, such references are merely descriptive and do not imply or require that the invention be implemented or used in a particular spatial orientation unless explicitly stated otherwise.

FIG. 1 is a diagram illustrating a roof including an example solar panel manufactured in accordance with an embodiment of the invention.

FIG. 2A (prior art) illustrates a conventional low profile solar assembly.

FIG. 2B (prior art) is a diagram illustrating the profile of a conventional low profile solar assembly.

FIG. 3 is a flowchart illustrating an example method for manufacturing a low profile solar laminate assembly in accordance with one embodiment of the present invention.

FIG. 4 is a diagram illustrating an example low profile solar laminate assembly in accordance with one embodiment of the present invention.

FIG. 5 illustrates an example low profile solar assembly in accordance with one embodiment of the present invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

The present invention is directed toward apparatuses and methods relating to low profile solar laminate assemblies. In the following paragraphs, the present invention will be described in detail by way of example with reference to the attached drawings. Throughout this description, the preferred embodiment and examples shown should be considered as exemplars, rather than as limitations on the present invention. As used herein, the “present invention” refers to any one of the embodiments of the invention described herein, and any equivalents. Furthermore, reference to various feature(s) of the “present invention” throughout this document does not mean that all claimed embodiments or methods must include the referenced feature(s).

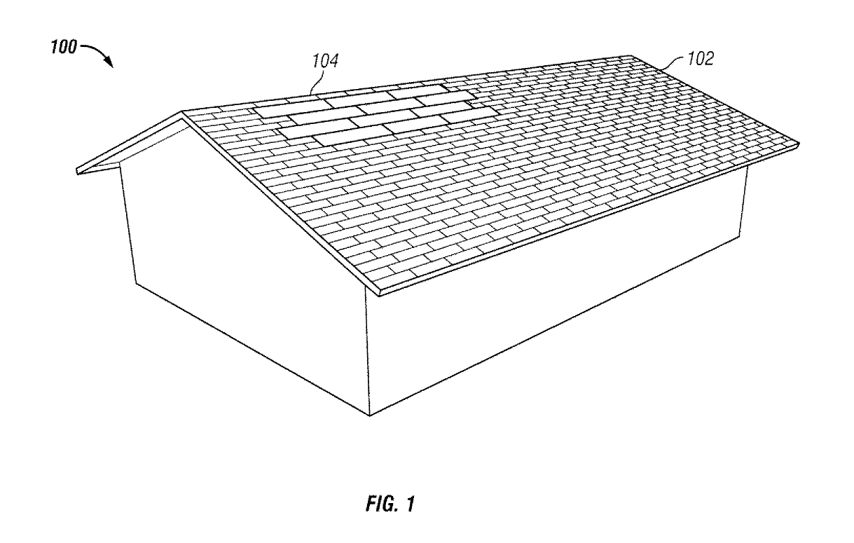

Referring now to the figures, FIG. 1 is a diagram illustrating a roof including an example set of solar panels manufactured in accordance with an embodiment of the invention. Referring now to FIG. 1, a roof, 100 is illustrated. The roof includes a number of shingles 102. The shingles 102 may be, for example, asphalt shingles, however, it will be understood that many other types of roof shingles may be used. Additionally, as illustrated in FIG. 1, the roof 100 may also include a solar panel 104.

The solar panel 104 may convert solar energy into electrical energy. This electricity may then be used by the homeowner to power the home, provide electrical energy back to the power grid to decrease electrical energy bills, or any other electrical use. In some example systems, solar panels may provide direct current electrical power. It will be understood that, in some embodiments, a system may convert this current to an alternating current electrical power source.

In another embodiment, a solar panel may collect solar energy to provide heat. The heat might increase the temperature of water or other liquid so that the heat might be carried into the home. The heat might then be used heat the home. In some examples, the water might be used for showering, laundry, etc. In some cases, the water might be in a sealed system that heats water in the home using a heat exchanger. The water heated using the heat exchanger might then be used for various purposes, such as showering, laundry, etc.

The example embodiment of FIG. 1 illustrates a solar power system that integrates the solar panels with roofing tiles. It will be understood, however, that in some embodiments, a roof might be entirely or almost entirely made using solar panels in accordance with the systems and methods described herein. Additionally, while the example illustrates solar panels that are incorporated into the roof 100, in some embodiments, the solar panels might form a new roof over an existing, e.g., shingle roof.

In some embodiments, a solar panel may comprise a thin profile, such that it might be incorporated into a shingle roof. For example, the solar panel might be installed similarly to roofing shingles, as illustrated in FIG. 1. These “solar shingles” may be connected to each other using a universal connector or jumper that can reverse polarity. The universal connector may facilitate stringing the panels together. By allowing polarity of the connection to be changed based on the orientation of a connector or jumper, the shingles may be installed and connected in various ways and configurations. For example, the shingles may be connected in parallel, in serial, or some combination of parallel and serial.

The solar panel 104 may comprise a solar cell or multiple solar cells. The solar cell or cells may be formed in a laminate. A laminate is a combination of one or more solar cells laminated with another material, e.g., a solar glass that efficiently collects more light to be converted to electrical energy by the solar cell. In this way, the laminated solar cells might be used to convert light in a broad range of frequency ranges to electrical energy.

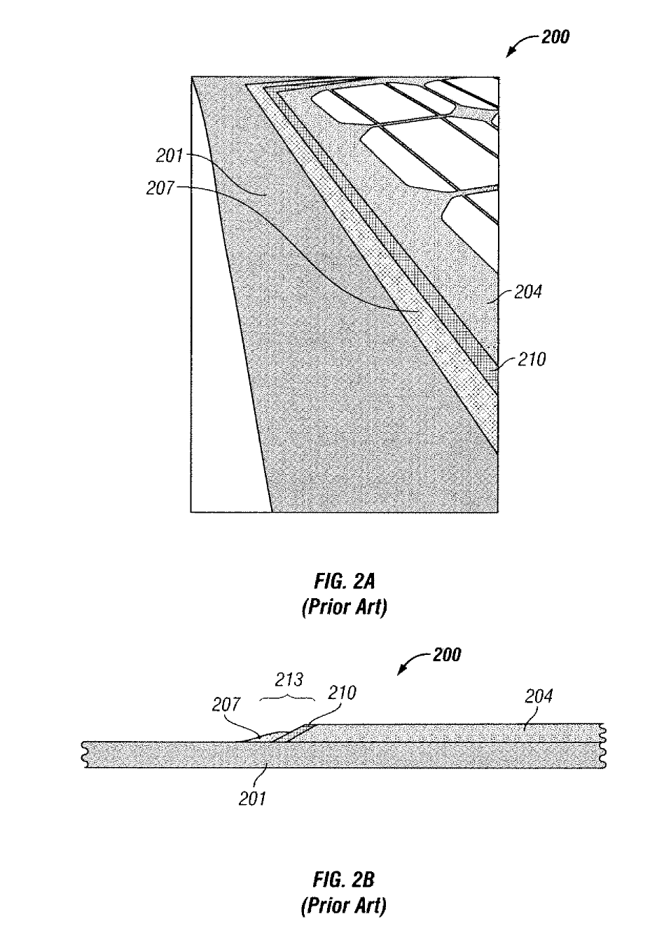

FIG. 2A (prior art) illustrates a conventional low profile solar assembly 200. FIG. 2B (prior art) provides a profile view of the same. Referring now to FIG. 2A, the assembly 200 comprises a photovoltaic laminate 204, a framed edged 210 around the perimeter of the photovoltaic laminate 204, a roofing membrane 201, and a sealant disposed between the framed edge and the membrane, thereby adhering and sealing the edge of the photovoltaic laminate 204 to the roofing membrane. As described earlier, options for sealant can include a bead of silicone, epoxy or urethane calking/adhesive.

As depicted in FIG. 2A, and better depicted in FIG. 2B, the resulting assembly 200 has a transitional lip/step 213 between the framed edged of the photovoltaic laminate 204 and the roofing membrane 201, As noted above, such a transition lip/step renders the assembly 200 susceptible to such problems as delamination, moisture integration, and collection of dirt and debris over the life of the BIPV panel. Additionally, during production, assembly 200 runs the risk of being produced as a product having low integrity. This is due in part to the difficulty in applying the sealant around the perimeter of the photovoltaic 204 laminate and the possibility of inconsistent sealing during the production process. Furthermore, because the sealant is exposed to ultraviolet light during operation, the sealant may suffer from discoloration from the ultraviolet exposure over time. Embodiments of the present invention overcome these issues.

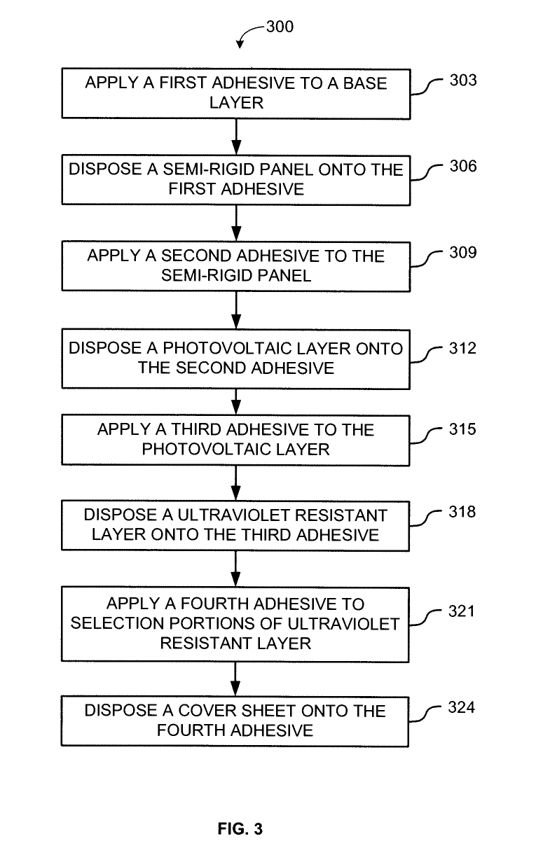

FIG. 3 is a flowchart illustrating an example method 300 for manufacturing a low profile solar laminate assembly in accordance with one embodiment of the present invention. Referring now to FIG. 3, method 300 begins with operation 303 where an adhesive, such as a glue, resin or sealant (e.g., silicon, epoxy, or urethane calking/adhesive), is applied to a rigid or semi-rigid base layer, such as polyvinyl chloride (PVC), thermoplastic olefin (TPO), ethylene propylene diene monomer (EPDM), a polyvinyl fluoride (PVF). Other electrically insolating materials, roofing materials, or roofing membranes may also be suitable as a base layer.

In operation 306, a semi-rigid panel is placed or disposed onto the first adhesive, thereby attaching the semi-rigid panel to the base layer. The semi-rigid panel should be of a material that sufficiently supports a photovoltaic layer, such as a fiber-reinforced plastic (FRP) or advance polymer alloys (APA).

Next, at operation 309, a second adhesive is applied to the semi-rigid panel such that a photovoltaic layer may be placed or disposed onto the semi-rigid panel at operation 312. The photovoltaic layer may comprise mono or polycrystalline solar cells.

Additionally, at operation 315, a third adhesive is applied to the photovoltaic layer such that an ultraviolet resistant layer may be placed or disposed onto the photovoltaic layer at operation 318. In some embodiments, the ultraviolet resistant layer is a film that filters out certain portions of ultraviolet light that reaches the photovoltaic layer. The ultraviolet resistant layer may be made of polycarbonate or polyethylene tetrafluoroethylene (ETFE)—such as Tefzel(®) by DuPont(™). Additionally, as previously noted, the third adhesive, and other adhesives, may be applied as a full or partial layer. As such, when the third adhesive is applied as a partial layer of adhesive, it should be applied such that light is allowed to pass through the ultraviolet resistant layer and still reach the photovoltaic layer. When the third adhesive is applied as a full layer of adhesive, it should be of the type that is light-transmissive and allows light to pass through the third adhesive and to the photovoltaic layer.

Optionally, for some embodiments, a fourth adhesive is applied to the ultraviolet resistant layer at operation 321 such that at cover sheet can be placed or disposed onto the ultraviolet resistant layer at operation 324. As previously mentioned, the cover sheet may be disposed onto the ultraviolet resistant layer such that it extends beyond its edge. In other embodiments, the cover sheet may be disposed on the ultraviolet resistant layer such that it allows for a seam weld to be formed between the low profile solar laminate and a roofing membrane.

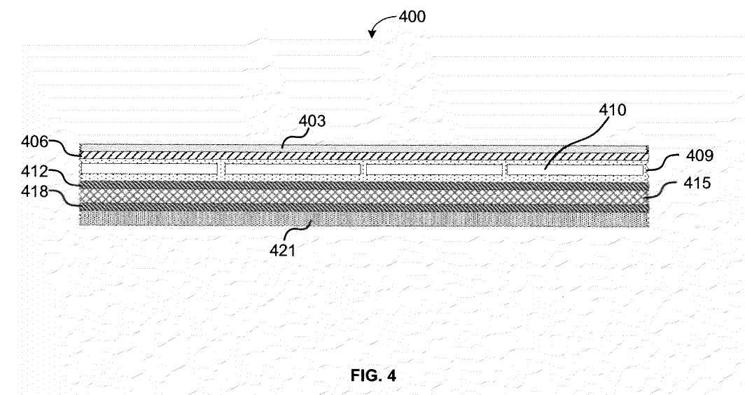

FIG. 4 is a diagram illustrating an example low profile solar laminate assembly 400 in accordance with one embodiment of the present invention. Specifically, FIG. 4 provides a profile view of low profile solar laminate assembly 400. Assembly comprises a base layer 421, an adhesive 418, a semi-rigid panel 415, an adhesive 412, a photovoltaic layer 409, an adhesive 406, and an ultraviolet resistant layer 403. In the depicted assembly 400, adhesive 406 is applied as a full layer covering the photovoltaic layer 409. As such, the adhesive 406 is of the type that is light-transmissive, thereby allowing light to pass through the adhesive 406 and reach the photovoltaic layer.

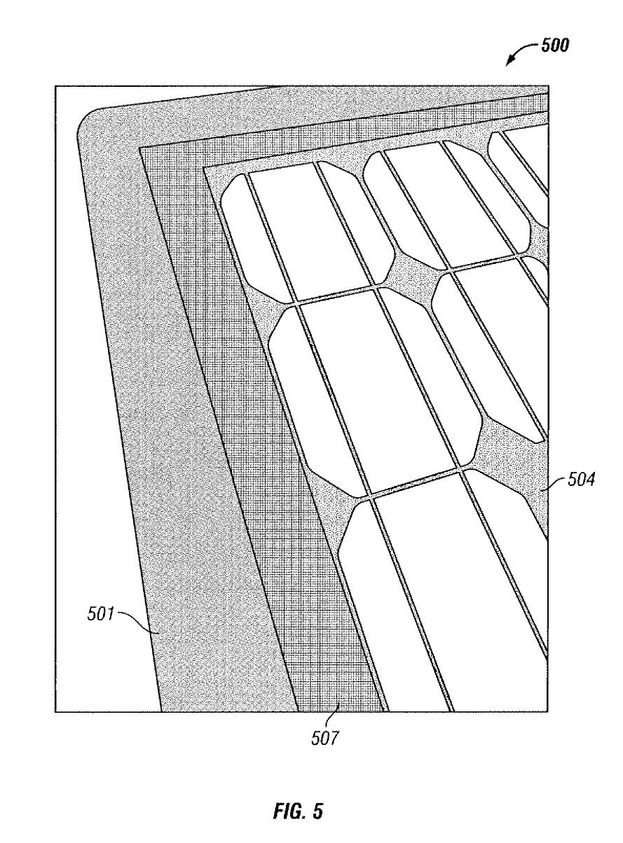

FIG. 5 illustrates an example low profile solar assembly 500 in accordance with one embodiment of the present invention. Referring now to FIG. 5, assembly 500 comprises a roofing membrane 501 and a low profile photovoltaic laminate 504. Also depicted is a cover sheet 507 that forms a seam weld between the low profile solar laminate and roofing membrane 501. As shown, there is no transitional lip between the laminate 504 and the roofing membrane 501. Accordingly, the depicted assembly overcomes some of the problems that plague the prior art.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A low profile solar laminate, comprising:
a base layer;
a photovoltaic layer;
a semi-rigid panel;
an ultraviolet resistant layer;
wherein a first adhesive adheres the base layer to the semi-rigid panel, a second adhesive adheres the semi-rigid panel to the photovoltaic layer, and a third adhesive adheres the ultraviolet resistant layer to the photovoltaic layer.

2. The low profile solar laminate of claim 1, wherein the base layer is made of an electrically insolating material.

3. The low profile solar laminate of claim 1, wherein the base layer is a roofing material or a roofing membrane.

4. The low profile solar laminate of claim 1, wherein the base layer is made of polyvinyl chloride (PVC), thermoplastic olefin (TPO), ethylene propylene diene monomer (EPDM), or polyvinyl fluoride (PVF).

5. The low profile solar laminate of claim 1, wherein the base layer is flexible or rigid.

6. The low profile solar laminate of claim 1, wherein the first, second, and third adhesives comprise a glue, a resin, or a sealant.

7. The low profile solar laminate of claim 1, wherein the semi-rigid panel is made of fiber-reinforced plastic (FRP) or advance polymer alloys (APA).

8. The low profile solar laminate of claim 1, wherein the ultraviolet resistant layer is made of polycarbonate or polyethylene tetrafluoroethylene (ETFE).

9. The low profile solar laminate of claim 1, wherein the photovoltaic cells comprise monocrystalline solar cells or polycrystalline solar cells.

10. The low profile solar laminate of claim 1, wherein the base material further comprising a cover sheet adhered to the ultraviolet resistant layer.

11. The low profile solar laminate of claim 10, wherein the cover sheet is disposed onto the ultraviolet resistant layer such that it extends beyond its edge.

12. The low profile solar laminate of claim 10, wherein the cover sheet is disposed on the ultraviolet resistant layer such that it allows for a seam weld to be formed between the low profile solar laminate and a roofing membrane.

13. A method for manufacturing a low profile solar laminate, comprising:
applying a first adhesive to a base layer;
disposing a semi-rigid panel onto the first adhesive;
applying a second adhesive to the semi-rigid panel;
disposing a photovoltaic layer onto the second adhesive;
applying a third adhesive to the photovoltaic layer; and
disposing an ultraviolet resistant layer onto the third adhesive.

14. The method of claim 13, further comprising disposing a cover sheet onto the ultraviolet resistant layer, wherein a fourth adhesive is used to adhere the cover sheet to the ultraviolet resistant layer.

15. The method of claim 13, wherein the base layer is made of an electrically insolating material.

16. The method of claim 13, wherein the base layer is a roofing material or a roofing membrane.

17. The method of claim 13, wherein the base layer is made of polyvinyl chloride (PVC), thermoplastic olefin (TPO), ethylene propylene diene monomer (EPDM), or polyvinyl fluoride (PVF).

18. The method of claim 13, wherein the base layer is flexible or rigid.

19. The method of claim 13, wherein the first, second, and third adhesives are a glue, a resin, or a sealant.

20. The method of claim 13, wherein the semi-rigid panel is made of fiber-reinforced plastic (FRP) or advance polymer alloys (APA).

21. The method of claim 13, wherein the ultraviolet resistant layer is made of polycarbonate or polyethylene tetrafluoroethylene (ETFE).

22. The method of claim 13, wherein the photovoltaic cells comprise monocrystalline solar cells or polycrystalline solar cells.

23. The method of claim 14, wherein the cover sheet is disposed onto the ultraviolet resistant layer such that it extends beyond its edge.

24. The method of claim 14, wherein the cover sheet is disposed on the ultraviolet resistant layer such that it allows for a seam weld to be formed between the low profile solar laminate and a roofing membrane.
